(19) United States
(12) Patent Application Publication
(10) Pub. No.: US 2024/0224711 A1
(43) Pub. Date: Jul. 4, 2024

(54) Organic Light Emitting Display Device

(71) Applicant: LG Display Co., Ltd., Seoul (KR)

(72) Inventor: KyoungMook Lee, Paju-si (KR)

(21) Appl. No.: 18/544,003

(22) Filed: Dec. 18, 2023

(30) Foreign Application Priority Data
Dec. 30, 2022 (KR) 10-2022-0190972

(51) Int. Cl. H10K 59/80; H10K 59/122; H10K 59/124

(52) U.S. Cl. CPC H10K 59/80522; H10K 59/122; H10K 59/124

(57) ABSTRACT

An organic light emitting display device comprises a substrate including a first sub pixel and a second sub pixel disposed in a first direction; a thin film transistor disposed on the substrate and corresponds to each of the first sub pixel and the second sub pixel; a planarization layer on the thin film transistor; an organic light emitting diode which is disposed on the planarization layer so as to correspond to each of the first sub pixel and the second sub pixel and has an anode, an organic emission layer, and a cathode; an auxiliary electrode between the first sub pixel and the second sub pixel; and a partition which is disposed on the auxiliary electrode so as to at least partially overlap the auxiliary electrode. The auxiliary electrode protrudes toward the first sub pixel and the second sub pixel from corners of the partition in plan view.

### CROSS-REFERENCE TO RELATED APPLICATIONS

This application claims the priority of Republic of Korea Patent Application No. 10-2022-0190972 filed on Dec. 30, 2022, in the Korean Intellectual Property Office, which is incorporated herein by reference in its entirety.

### BACKGROUND

### Field

The present disclosure relates to an organic light emitting display device, and more particularly, to a top-emission type organic light emitting display device with an improved luminance uniformity.

### Description of the Related Art

The organic light emitting display device is a self-emitting display device so that a separate light source is not necessary, which is different from the liquid crystal display device. Therefore, the organic light emitting display device may be manufactured to have light weight and small thickness. Further, since the organic light emitting display device is driven at a low voltage, it is advantageous not only in terms of power consumption, but also in the response speed, the viewing angle, and the contrast ratio, so that the electroluminescence display apparatus is being studied as next generation displays.

A top-emission type organic light emitting display device, among organic light emitting display devices, uses a transparent electrode or a transflective electrode, as a cathode, to emit light emitted from an organic emission layer to an upper portion of the organic light emitting display device. In order to acquire sufficient light transmittance to pass through the cathode, the cathode needs to be formed with a very thin thickness. Accordingly, the cathode is formed of an alloy of silver (Ag) and magnesium (Mg) or a transparent conductive oxide TCO with a sufficiently thin thickness. However, the thickness reduction of the cathode increases an electric resistance of a cathode electrode. By doing this, in the case of an organic light emitting display with a large area, the further away from a Vss voltage supply pad unit which applies a voltage Vss to the cathode, the more severe the voltage drop occurs so that the luminance non-uniformity problem of the organic light emitting display device may be caused. In the present specification, the voltage drop refers to a phenomenon that a potential difference formed in an organic light emitting diode is reduced, and specifically, refers to reduction of a potential difference between an anode and a cathode of the organic light emitting diode.

In order to solve the voltage drop, a technique which uses an auxiliary electrode which is electrically connected to the cathode is being used. The auxiliary electrode which is electrically connected to a Vss voltage supply pad unit and extends from the Vss voltage supply pad is electrically connected to the cathode in an arbitrary area of the active area, to relieve the voltage drop.

However, in order to form the auxiliary electrode, an auxiliary electrode which is formed on a planarization layer with the same material as the anode or a source/drain electrode is being used. However, generally, in the case of the top-emission type organic light emitting display device, it is difficult to form a contact hole for connecting the cathode and the auxiliary electrode during the process.

### SUMMARY

Accordingly, an object to be achieved by the present disclosure is to provide an organic light emitting display device which improves the luminance uniformity and implements a high resolution.

Further, another object to be achieved by the present disclosure is to provide an organic light emitting display device which solves a contact failure of the auxiliary electrode and the cathode due to misalignment of a partition, during a process of forming the auxiliary electrode and the partition.

Further, an object to be achieved by the present disclosure is to provide an organic light emitting display device which allows the contact of the auxiliary electrode and the cathode without an additional mask process.

Objects of the present disclosure are not limited to the above-mentioned objects, and other objects, which are not mentioned above, can be clearly understood by those skilled in the art from the following descriptions.

According to an embodiment of the present disclosure, an organic light emitting display device includes a substrate which includes a first sub pixel and a second sub pixel disposed in a first direction; a thin film transistor which is disposed on the substrate and corresponds to each of the first sub pixel and the second sub pixel; a planarization layer on the thin film transistor; an organic light emitting diode which is disposed on the planarization layer so as to correspond to the first sub pixel and the second sub pixel and has an anode, an organic emission layer, and a cathode; an auxiliary electrode disposed between the first sub pixel and the second sub pixel; and a partition which is disposed on the auxiliary electrode so as to at least partially overlap the auxiliary disposed, the auxiliary electrode protrudes toward the first sub pixel and the second sub pixel from corners of the partition in plan view.

According to another embodiment of the present disclosure, an organic light emitting display device includes a first sub pixel, a second sub pixel, an auxiliary electrode between the first sub pixel and the second sub pixel, and a partition on the auxiliary electrode. The first sub pixel includes a first anode electrode, a first organic light emitting layer, and a first cathode electrode. The second sub pixel includes a second anode electrode, a second organic light emitting layer, and a second cathode electrode. The auxiliary electrode is disposed on at least a first planarization layer and comprises at least a first portion and a second portion. The first portion protrudes further than an edge of the second portion in a first direction. The partition at least partially overlaps the auxiliary electrode.

Other detailed matters of the exemplary embodiments are included in the detailed description and the drawings.

According to the present disclosure, a structural characteristic of the auxiliary electrode which is disposed between two sub pixels allows the auxiliary electrode and the cathode to be in stably contact with each other regardless of the misalignment generated during the formation of the partition. Therefore, the luminance non-uniformity problem which may be caused by the voltage drop may be solved and the resolution of the organic light emitting device may be improved.

Further, according to the present disclosure, a process difficulty is lowered and a process cost is reduced.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of an organic light emitting display device according to an exemplary embodiment of the present disclosure.

FIG. 2 is an enlarged plan view of an area A of FIG. 1, according to an embodiment of the present disclosure.

FIG. 3 is a cross-sectional view taken along the line I-I′ of FIG. 2, according to an embodiment of the present disclosure.

FIG. 4 is a cross-sectional view taken along the line II-II′ of FIG. 2, according to an embodiment of the present disclosure.

FIGS. 5 to 8 are cross-sectional views illustrating various exemplary embodiments for a formation position of an auxiliary electrode and a partition in an organic light emitting display device according to another exemplary embodiment of the present disclosure.

FIG. 9 is a cross-sectional view illustrating a structure of an auxiliary electrode and a partition in an organic light emitting display device according to still another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an organic light emitting display device according to exemplary embodiments of the present disclosure will be described in detail with reference to accompanying drawings.

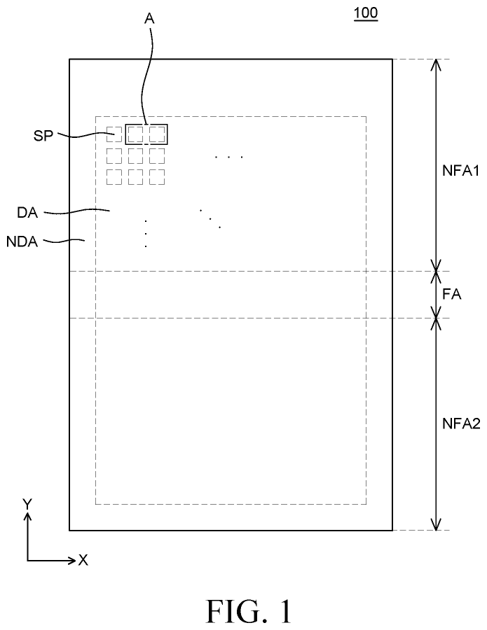

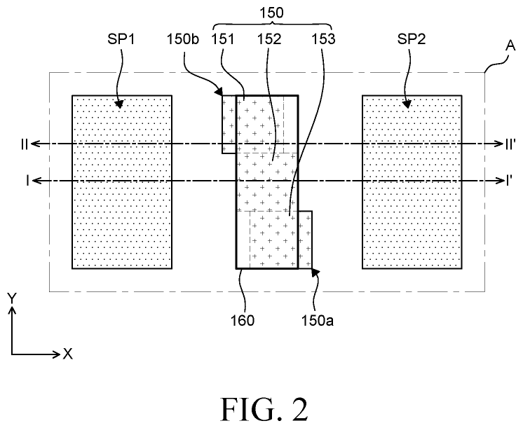

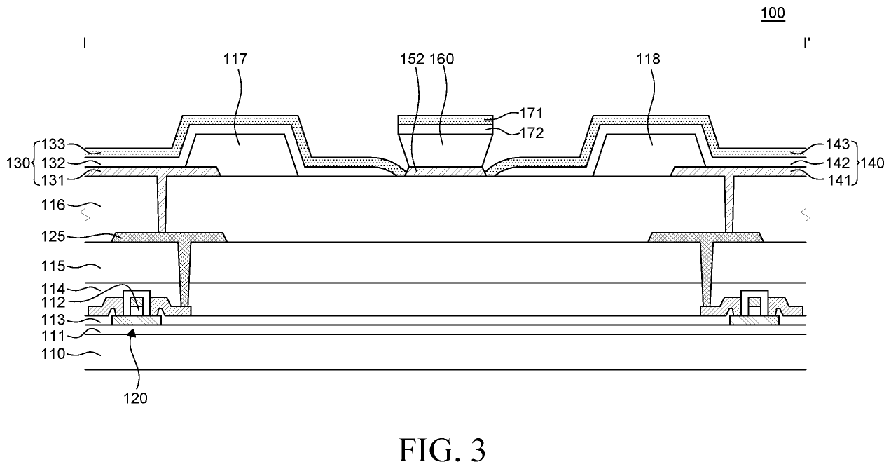

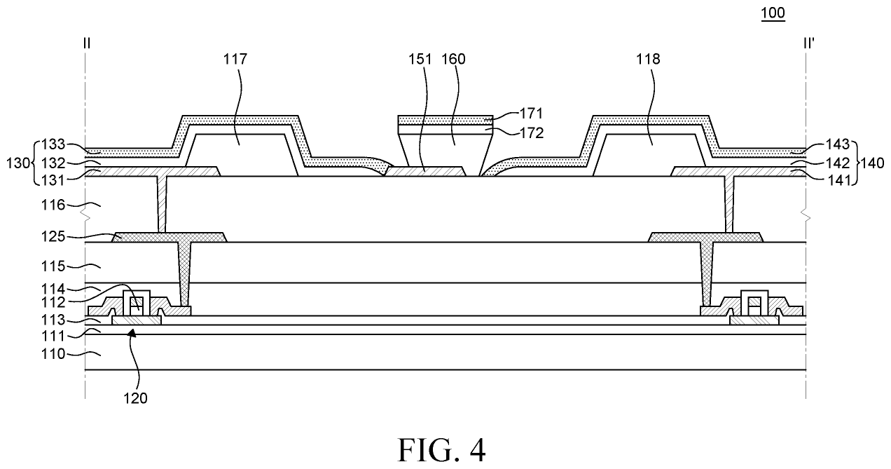

FIGS. 1 to 4 are views for explaining an organic light emitting display device according to an exemplary embodiment of the present disclosure. FIG. 1 is a schematic plan view of an organic light emitting display device according to an exemplary embodiment of the present disclosure. FIG. 2 is an enlarged plan view of an area A of FIG. 1. FIG. 3 is a cross-sectional view taken along the line I-I′ of FIG. 2. FIG. 4 is a cross-sectional view taken along the line II-II′ of FIG. 2.

Referring to FIGS. 1 to 4, an organic light emitting display device 100 according to an exemplary embodiment of the present disclosure includes a substrate 110, a first organic light emitting diode 130, a second organic light emitting diode 140, a first bank layer 117, a second bank layer 118, an auxiliary electrode 150, and a partition 160.

Referring to FIG. 1, the organic light emitting display device 100 according to the exemplary embodiment of the present disclosure includes a display area DA and a non-display area NDA. The display area DA is an area where a plurality of sub pixels SP is disposed to substantially display images. For example, each of the plurality of sub pixels SP may be configured to emit red light, green light, blue light, or white light.

In the display area DA, a plurality of sub pixels SP including an emission area for displaying images and a driving circuit for driving the sub pixels SP may be disposed. A sub pixel SP is an element which displays one color and includes an emission area where light is emitted and a non-emission area where light is not emitted, but in the specification, only the emission area where the light is emitted is defined as a sub pixel. The plurality of sub pixels SP is disposed in a matrix. The non-display area NDA encloses the display area DA. The non-display area NDA is an area where images are not substantially displayed and various wiring lines, driving ICs, and printed circuit boards for driving the pixels and the driving circuits disposed in the display area DA are disposed. For example, in the non-display area NDA, various driving ICs such as a gate driver IC and a data driver IC and VSS lines may be disposed.

The plurality of sub pixels SP is disposed in a matrix. The plurality of sub pixels SP may configure one pixel unit. The color and the arrangement of the plurality of sub pixels SP may vary in various forms depending on the necessity. Further, in FIG. 2, it is illustrated that the plurality of sub pixels SP1 and SP2 has a quadrangular shape, but it is not limited thereto and the shape of the sub pixels may be changed to various shapes. For example, each sub pixel may have a polygonal shape other than a circular shape, an oval shape, or an octagonal shape.

The organic light emitting display device 100 may be a foldable display device which is foldable with respect to a folding axis. At this time, the organic light emitting display device 100 is divided into a folding area FA and non-folding areas NFA1 and NFA2 depending on whether to be folded. The folding area FA is an area which is folded when the organic light emitting display device 100 is folded and is folded in accordance with a specific radius of curvature with respect to a folding axis. For example, the folding axis of the folding area FA may be formed in an X-axis direction (or a first direction) and the non-folding areas NFA1 and NFA2 may extend from the folding area FA in a Y-axis direction (or a second direction) which is perpendicular to the folding axis. When the folding area FA is folded with respect to the folding axis, the folding area FA may form a part of a circle or an oval. At this time, a radius of curvature of the folding area FA may refer to a radius of a circle or an oval formed by the folding area FA.

Therefore, a partial area of the organic light emitting display device 100 may be a display area DA and a folding area FA and the other partial area of the organic light emitting display device 100 may be a non-display area NDA and the non-folding areas NFA1 and NFA2.

In the meantime, when a surface of the organic light emitting display device 100 on which images are displayed is defined as a top surface and a rear surface of the organic light emitting display device 100 is defined as a bottom surface, the folding unit FA may be folded by a method selected from an outer-folding method and an in-folding method. According to the outer-folding method, the folding units are folded to expose the top surface of the organic light emitting display device 100 to the outside and according to the in-folding (or inner-folding) method, the folding units are folded to expose the bottom surface of the organic light emitting display device 100 to the outside.

The substrate 110 supports and protects several components of the organic light emitting display device 100. The substrate 110 is configured by an insulating material, and for example, may be formed of glass or plastic, but is not limited thereto and may be formed of various materials. When the organic light emitting display device 100 is used as a foldable display device, the substrate may be a flexible substrate which is formed of an insulating material having a flexibility. For example, the flexible substrate 110 may be an insulating plastic substrate selected from polyimide, polyethersulfone, polyethylene terephthalate, and polycarbonate. However, it is not limited thereto and if a material is not broken even when the organic light emitting display device 100 is repeatedly folded, not only the plastic, but also a material having a flexibility may be used.

Referring to FIG. 2, a first sub pixel SP1 and a second sub pixel SP2 are disposed on the substrate 110. The first sub pixel SP1 and the second sub pixel SP2 may be disposed to be opposite to each other in the X-axis direction. Specifically, the first sub pixel SP1 and the second sub pixel SP2 are arbitrary sub pixels, among the plurality of sub pixels, and may be any one of a red sub pixel, a green sub pixel, and a blue sub pixel. The auxiliary electrode 150 and the partition 160 are disposed between the first sub pixel SP1 and the second sub pixel SP2. The auxiliary electrode 150 and the partition 160 will be described in detail below.

The thin film transistor 120 is formed on the substrate 110. The thin film transistor 120 is formed in each of the first sub pixel SP1 and the second sub pixel SP2. Specifically, a buffer layer 111 is disposed on the substrate 110 and an active layer in which a channel of the thin film transistor 120 is formed is formed on the buffer layer 111. The buffer layer 111 is to prevent moisture from permeating from the outside, and may be formed by inorganic film in a single layer or in multiple layers. As illustrated in FIG. 3, the active layer may be formed on the buffer layer 111 and if the buffer layer 111 is not used, the active layer may be formed immediately on the substrate 110. In order to insulate the active layer from the gate electrode, a gate insulating layer 112 is formed on the active layer. The gate electrode is formed on the gate insulating layer 112. An interlayer insulating layer 113 is disposed on the gate electrode. The interlayer insulating layer 113 is formed on the entire substrate 110 and has a contact hole to open a partial area of the active layer. The source electrode and the drain electrode are formed on the interlayer insulating layer 113 and each of the source electrode and the drain electrode is electrically connected to the active layer through a contact hole. Even though in FIG. 3, for the convenience of description, it is illustrated that the thin film transistor 120 has a coplanar structure, the present disclosure is not limited thereto and the thin film transistor 120 may also be formed with an inverted staggered structure. Further, even though in FIG. 3, for the convenience of description, only a driving thin film transistor 120, among various driving elements, is illustrated, a switching thin film transistor or a storage capacitor may be formed. A passivation layer 114 for protecting the thin film transistor 120 may be formed on the source electrode and the drain electrode. However, according to various exemplary embodiments of the present disclosure, the configuration and the placement of the thin film transistor TFT may vary as needed.

A first planarization layer 115 is disposed on the passivation layer 114. The first planarization layer 115 is an insulating layer which planarizes an upper portion of the substrate 110. The first planarization layer 115 may be formed of an organic material, and for example, may be configured by a single layer or a double layer of polyimide or photo acryl, but is not limited thereto.

A connection electrode 125 is disposed on the first planarization layer 115. The connection electrode 125 is an intermediate layer for connecting the drain electrode of the thin film transistor 120 and the anode 131 of the organic light emitting diode 130. The connection electrode 125 may be configured by a conductive material, such as copper (Cu), aluminum (Al), molybdenum (Mo), nickel (Ni), titanium (Ti), chrome (Cr), or an alloy thereof, but is not limited thereto. However, the connection electrode 125 may be formed of the same material as the high potential power line and the data line.

A second planarization layer 116 is disposed on the connection electrode 125. The second planarization layer 116 is an insulating layer which planarizes an upper portion of the substrate 110. The second planarization layer 116 may be formed of an organic material, and for example, may be configured by a single layer or a double layer of polyimide or photo acryl, but is not limited thereto.

The first organic light emitting diode 130 and the second organic light emitting diode 140 are formed on the second planarization layer 116. The first organic light emitting diode 130 is formed in the first sub pixel SP1 and the second organic light emitting diode 140 is formed in the second sub pixel SP2. The first organic light emitting diode 130 includes a first anode 131, a first organic emission layer 132, and a first cathode 133 and the second organic light emitting diode 140 includes a second anode 141, a second organic emission layer 142, and a second cathode 143.

The first anode 131 and the second anode 141 are formed on the single second planarization layer 116 in the first sub pixel SP1 and the second sub pixel SP2, respectively. Each of the first anode 131 and the second anode 141 is electrically connected to the thin film transistor 120 formed in the first sub pixel SP1 and the second sub pixel SP2. Since the organic light emitting display device 100 according to the exemplary embodiment of the present disclosure is a top emission type organic light emitting display device. Therefore, the first anode 131 and the second anode 141 includes a reflective layer which is a conductive layer having excellent reflectance and a transparent conductive layer formed on the reflective layer. The transparent conductive layer is formed of transparent conductive oxide, such as indium tin oxide (ITO) or indium zinc oxide (IZO) having a high work function to supply holes to the first organic emission layer 132 and the second organic emission layer 142. In some exemplary embodiments, the transparent conductive oxide of the transparent conductive layer may be polymerized by a curing process on the first bank layer 117 and the second bank layer 118. Accordingly, the first anode 131 and the second anode 141 may include a polymerized transparent conductive oxide.

A bank layer is formed on the second planarization layer 116. The bank layer serves to define a sub pixel. Thus, the bank layer may be made of an insulating material containing a black material. The bank layer may be made of, for example, a transparent carbon-based mixture. Specifically, the bank layer may contain carbon black, but is not limited thereto. The bank layer may also be made of a transparent insulating material. The bank layer includes a first bank layer 117 and a second bank layer 118. The first bank layer 117 covers an edge of the first anode 131 to open a part of a top surface of the first anode 131 to define an emission area of the first sub pixel SP1. Further, the second bank layer 118 covers an edge of the second anode 141 to open a part of a top surface of the second anode 141 to define an emission area of the second sub pixel SP2. As described above, in the present specification, only an emission area in which light is emitted is defined as a sub pixel SP.

The auxiliary electrode 150 is formed on the second planarization layer 116. Referring to FIG. 2, the auxiliary electrode 150 is disposed between the first sub pixel SP1 and the second sub pixel SP2 and referring to FIG. 3, is formed between the first bank layer 117 and the second bank layer 118.

The auxiliary electrode 150 is formed of the same material as the first anode 131 and the second anode 141. As described above, when the first anode 131 and the second anode 141 are formed of the reflective layer and the transparent conductive layer, the auxiliary electrode 150 is also formed with a structure in which the reflective layer and the transparent conductive layer are laminated. The auxiliary electrode 150, the first anode 131, and the second anode 141 may be formed with the same thickness. In some exemplary embodiments, as described above, the transparent conductive oxide of the transparent conductive layer of the first anode 131 and the second anode 141 is polymerized by the curing process on the bank layer. Accordingly, the first bank layer 117 and the second bank layer 118 also include a polymerized transparent conductive oxide.

Referring to FIG. 2, the auxiliary electrode 150 is disposed in the non-emission area between the first sub pixel SP1 and the second sub pixel SP2. The auxiliary electrode 150 extends in the Y-axis direction. At this time, the auxiliary electrode 150 may have a shape which sequentially forms steps in the X-axis direction while extending in the Y-axis direction.

Specifically, the auxiliary electrode 150 includes a plurality of auxiliary electrode blocks 151, 152, and 153. Specifically, the auxiliary electrode 150 includes a first auxiliary electrode block 151, a second auxiliary electrode block 152, and a third auxiliary electrode block 153. The first auxiliary electrode block 151, the second auxiliary electrode block 152, and the third auxiliary electrode block 153 have the same length and width. The first auxiliary electrode block 151, the second auxiliary electrode block 152, and the third auxiliary electrode block 153 are continuously arranged in the Y-axis direction to be sequentially connected, between the first sub pixel SP1 and the second sub pixel SP2 which are opposite to each other in the X-axis direction.

In the meantime, the first auxiliary electrode block 151, the second auxiliary electrode block 152, and the third auxiliary electrode block 153 are disposed to move in the X-axis direction while being sequentially arranged in the Y-axis direction. Specifically, the second auxiliary electrode block 152 is disposed below the first auxiliary electrode block 151 in the Y-axis direction and is shifted to the right direction by a predetermined distance with respect to the X-axis direction. By doing this, the first auxiliary electrode block 151 and the second auxiliary electrode block 152 form a step and the second auxiliary electrode block 152 protrudes to the right direction more than the first auxiliary electrode block 151. Next, the third auxiliary electrode block 153 is disposed below the second auxiliary electrode block 152 in the Y-axis direction and is shifted to the right direction by a predetermined distance with respect to the X-axis direction. By doing this, the second auxiliary electrode block 152 and the third auxiliary electrode block form a step and the third auxiliary electrode block 153 protrudes to the right direction more than the second auxiliary electrode block 152. A distance of the second auxiliary electrode block 152 shifted from the first auxiliary electrode block 151 is equal to a distance of the third auxiliary electrode block 153 shifted from the second auxiliary electrode block 152. By doing this, the auxiliary electrode 150 forms a plurality of step structures in plan view while extending to the Y-axis direction.

It is to be noted that, although the auxiliary electrode 150 is shown as first to third auxiliary electrode blocks forming a plurality of step structures in FIG. 2, the present disclosure is not limited thereto. For example, the auxiliary electrode according to example embodiments of the present disclosure may just have a shape that protrudes from corners of the partition in a plan view toward the first sub-pixel and the second sub-pixel, respectively. In addition, the arrangement of the auxiliary electrode in region A shown in FIG. 2 may be equally or similarly applied to any other regions shown in FIG. 1. In order words, the auxiliary electrode may be regularly disposed in a array in the organic light emitting display device.

In other words, the first auxiliary electrode block 151 which is disposed above the second auxiliary electrode block 152 is shifted to the left direction by a predetermined distance. Further, the third auxiliary electrode block 153 which is disposed below the second auxiliary electrode block 152 is shifted to the right direction by a predetermined distance. By doing this, with respect to a center axis of the second auxiliary electrode block 152 disposed in the middle in the Y direction, the first auxiliary electrode block 151 protrudes toward the first sub pixel SP1 more than the second auxiliary electrode block 152. Further, the third auxiliary electrode block 153 protrudes toward the second sub pixel SP2 more than the second auxiliary electrode block 152.

Accordingly, the auxiliary electrode 150 extends in the Y-axis direction to form a first protrusion 150a protruding toward the first sub pixel SP1 in an upper direction and a second protrusion 150b protruding toward the second sub pixel SP2 in a lower direction.

One side of the auxiliary electrode 150 protrudes toward the first sub pixel SP1 and the other side protrudes toward the second sub pixel SP2. Therefore, the failure in which the contact with the first cathode 133 and/or the second cathode 143 is not formed due to the misalignment of the partition 160 disposed above the auxiliary electrode 150 may be suppressed. A specific description thereof will be described below together with the partition 160.

The partition 160 may be formed on the common electrode 150. A bottom surface of the partition 160 is formed to be in direct contact with a top surface of the auxiliary electrode 150. The partition 160 may be formed to have a reverse taper shape to disconnect the first organic emission layer 132 and the second organic emission layer 142 from each other. That is, a cross-sectional area of the partition 160 is increased as the distance from the second planarization layer 116 is increased so that an area of the top surface of the partition 160 is larger than an area of the bottom surface of the partition 160. In order to form the partition 160 with a reverse taper shape, the partition 160 may be formed with a negative type photoresist. FIG. 2, it is illustrated that the partition 160 is formed with a single reverse taper shape, but it is not limited thereto and the partition 160 may be formed with a double reverse taper or a triple or more reverse taper shape.

The partition 160 and the first bank layer 117 and the second bank layer 118 do not overlap. Referring to FIG. 3, the first bank layer 117 and the second bank layer 118 may be formed at the outside from both corners of the partition 160 in the X-axis direction. As described above, in order to form the partition 160 in a reverse taper shape, after applying a negative type photoresist, the exposure and the development are partially performed to form the partition 160 with a reverse taper shape. However, when the first bank layer 117 and the second bank layer 118 are formed in an area for forming the partition 160, the negative type photoresist may not be evenly applied in the area for forming the partition 160 so that a partition 160 with a desired shape may not be formed. Accordingly, in the organic light emitting display device 100 according to the exemplary embodiment of the present disclosure, the first bank layer 117 and the second bank layer 118 are disposed so as not to overlap the partition 160.

In the meantime, as described above, the auxiliary electrode 150 is shifted to the X-axis direction while forming the step to extend in the Y-axis direction. Referring to FIG. 2, the auxiliary electrode 150 includes a first protrusion 150a protruding toward the first sub pixel SP1 and a second protrusion 150b protruding toward the second sub pixel SP2. By doing this, the partition 160 may be disposed so as not to overlap at least a part of the auxiliary electrode 150 in plan view.

Referring to FIG. 2, the partition 160 has a shape which is elongated in the Y-axis direction. For example, the partition 160 has a rectangular shape. At this time, at least a part of the partition 160 does not overlap the auxiliary electrode 150 in plan view. Specifically, the partition 160 is disposed so as to correspond to the second auxiliary electrode block 152 in plan view. That is, a width of the bottom surface of the partition 160 is equal to a width of the second auxiliary electrode block 152. Accordingly, a side surface of the second auxiliary electrode block 152 is exposed to be in contact with the cathode.

However, at least one side of the partition 160 does not overlap the first auxiliary electrode block 151 and the third auxiliary electrode block 153. Referring to FIGS. 2 and 4, the first auxiliary electrode block 151 is shifted to the left direction more than the second auxiliary electrode block 152. Therefore, a left side surface of the first auxiliary electrode block 151 protrudes toward the first sub pixel SP1 more than the partition 160 and a right side surface of the first auxiliary electrode block 151 is covered by the partition 160 so as not to be exposed to the outside. Accordingly, the left side surface of the first auxiliary electrode block 151 is in contact with the cathode 133 of the first organic light emitting diode 130, but the right side surface of the first auxiliary electrode block 151 is not in contact with the cathode 143 of the second organic light emitting diode 140.

Similarly, the third auxiliary electrode block 153 is shifted to the right direction more than the second auxiliary electrode block 152. Therefore, a right side surface of the third auxiliary electrode block 153 protrudes toward the second sub pixel SP2 more than the partition 160 and a left side surface of the third auxiliary electrode block 153 is covered by the partition 160 so as not to be exposed to the outside. Accordingly, the right side surface of the third auxiliary electrode block 153 is in contact with the cathode of the second organic light emitting diode, but the left side surface of the third auxiliary electrode block 151 is not in contact with the cathode of the first organic light emitting diode.

In the organic light emitting display device 100 according to the exemplary embodiment of the present disclosure, due to the structural characteristic of the auxiliary electrode 150, the partition 160 does not completely overlap the auxiliary electrode 150 during the process, but the cathode and the auxiliary electrode 150 may be in stably contact with each other. Specifically, generally, when the auxiliary electrode has a quadrangular shape or extends in one direction, like the wiring line, if a partition disposed thereabove is slightly deviated to a different direction from the extending direction of the auxiliary electrode or is misaligned, in a partial area, the cathode and the auxiliary electrode are not in contact. For example, when the auxiliary electrode and the partition which are elongated in the Y-axis direction overlap, if the partition is slightly misaligned to the right direction, the right side surface of the auxiliary electrode is covered by the partition so that the contact with the cathode is not possible. In this case, only the voltage Vss is supplied only to the organic light emitting diode located at the left side of the auxiliary electrode, but the voltage Vss is not supplied to the organic light emitting diode located at the right side, so that finally, the emission performance is not uniform or degraded.

However, the organic light emitting display device 100 illustrated in FIGS. 2 to 4 has a structure in which unit electrode blocks 151, 152, and 153 which configure the auxiliary electrode 150 are shifted toward the first sub pixel SP1 or the second sub pixel SP2. By doing this, a first protrusion 150a directed to the first sub pixel SP1 and a second protrusion 150b directed to the second sub pixel SP2 are formed. When the partition 160 is formed, even though a center of the partition 160 does not coincide with the center of the auxiliary electrode 150, but is biased to one side, the auxiliary electrode 150 and the cathodes 133 and 143 are in contact with each other in both directions, by the first protrusion 150a or the second protrusion 150b. By doing this, the process is easy, but the defect is significantly reduced.

The first organic emission layer 132 is formed on the first anode 131 and the second organic emission layer 142 is formed on the second anode 141. The first organic emission layer 132 and the second organic emission layer 142 are formed by depositing the same organic emission material on the entire substrate 110. The organic emission material is a material having an inferior step coverage so that the first organic emission layer 132 and the second organic emission layer 142 are formed in an area which is not blocked by the partition 160. Accordingly, the first organic emission layer 132 is formed on the first anode 131 in the first sub pixel SP1 and is formed on the first bank layer 117 adjacent to the auxiliary electrode 150 and the second planarization layer 116. Further, the second organic emission layer 142 is formed on the second anode 141 in the second sub pixel SP2 and is formed on the second bank layer 118 adjacent to the auxiliary electrode 150 and the second planarization layer 116.

Referring to FIG. 3, the first organic emission layer 132 and the second organic emission layer 142 are spaced apart from the auxiliary electrode 150, but may extend to partially overlap the partition 160. As described above, the organic emission material which configures the first organic emission layer 132 and the second organic emission layer 142 has an inferior step coverage so that the organic emission material may not be deposited in an area overlapping the partition 160. However, when the organic emission material is deposited, as illustrated in FIG. 3, the organic emission material may permeate underneath the partition 160. Accordingly, the first organic emission layer 132 and the second organic emission layer 142 may be formed on the second planarization layer 116 so as to overlap the partition 160.

The first organic emission layer 132 and the second organic emission layer 142 may be organic emission layers which emit same color light. For example, the first organic emission layer 132 and the second organic emission layer 142 may be a white organic emission layer, a red organic emission layer, a green organic emission layer, and a blue organic emission layer. When the first organic emission layer 132 and the second organic emission layer 142 are white organic emission layers, a color filter is disposed above the organic light emitting diode.

A dummy organic layer 171 is formed on the partition 160. That is, the dummy organic layer 171 is formed of the same material as the first organic emission layer 132 and the second organic emission layer 142. When the organic emission material is deposited so as to form the first organic emission layer 132 and the second organic emission layer 142, the dummy organic layer 171 is formed on the partition 160.

The first cathode 133 is formed on the first organic emission layer 132 and the second cathode 143 is formed on the second organic emission layer 142. The first cathode 133 and the second cathode 143 supply electrons to the first organic emission layer 132 and the second organic emission layer 142, respectively. The first cathode 133 and the second cathode 143 may be formed by depositing the same conductive material on the entire substrate 110. For example, the first cathode 133 and the second cathode 143 may be formed by depositing transparent conductive oxide, such as ITO or IZO, on the entire substrate 110. The transparent conductive oxide is a material having excellent step coverage so that the first cathode 133 and the second cathode 143 permeate the second planarization layer 116 overlapping the partition 160 to be in contact with the auxiliary electrode 150. Accordingly, the first cathode 133 extends toward the auxiliary electrode 150 to be formed on the first organic emission layer 132 and the second planarization layer 116 and is in direct contact with the side surface of the auxiliary electrode 150. Further, the second cathode 143 extends toward the auxiliary electrode 150 to be formed on the second organic emission layer 142 and the second planarization layer 116 and is in direct contact with the side surface of the auxiliary electrode 150.

A dummy conductive layer 172 is formed on the dummy organic layer 171. The dummy conductive layer 172 is formed of the same material as the first cathode 133 and the second cathode 143. That is, when the transparent conductive oxide is deposited to form the first cathode 133 and the second cathode 143, the dummy conductive layer 172 is formed on the dummy organic layer 171.

As illustrated in FIGS. 1-3, in some embodiments, an organic light emitting display device includes a first sub pixel SP1, a second sub pixel SP2, an auxiliary electrode 150 between the first sub pixel SP1 and the second sub pixel SP2, and a partition 160 on the auxiliary electrode 150. The first sub pixel SP1 includes a first anode electrode (e.g., first anode 131), a first organic light emitting layer 132, and a first cathode electrode (e.g., first cathode 133). The second sub pixel SP2 includes a second anode electrode (e.g., first anode 141), a second organic light emitting layer 142, and a second cathode electrode (e.g., second cathode 143). The auxiliary electrode 150 is disposed on at least a first planarization layer (e.g., planarization layer 115) and includes at least a first portion 151 and a second portion 152. The first portion 151 protrudes further than an edge of the second portion 152 in a first direction (e.g., −x direction toward the first sub pixel SP1). The partition 160 at least partially overlaps the auxiliary electrode 150. In some embodiments, the auxiliary electrode further includes a third portion 153 that protrudes further than another edge of the second portion 152 of the auxiliary electrode 150 in a second direction (e.g., +x direction toward the second sub pixel SP2) opposite to the first direction (e.g., −x direction). In some embodiments, the first cathode electrode (e.g., first cathode 133) is electrically connected to the auxiliary electrode 150, and the first anode electrode, the second anode electrode, and the auxiliary electrode include a same material.

In some embodiments, the first cathode electrode (e.g., first cathode 133) contacts the first portion 151 of the auxiliary electrode 150, and the second cathode electrode (e.g., second cathode 143) contacts the third portion 153 of the auxiliary electrode 150. In some embodiments, the partition 160 covers an edge of the first portion 151 of the auxiliary electrode 150.

In the related art, an organic light emitting display device which used a rectangular or a wiring line type auxiliary electrode on the planarization layer was used. However, when the auxiliary electrode with this structure was used, if the partition disposed above the auxiliary electrode was slightly biased during the process, there was problem in that the contact with the cathode was difficult. In this case, even though the auxiliary electrode was used, the voltage drop problem was still generated and the defect was also generated during the process of forming the auxiliary electrode and the partition.

Therefore, in the organic light emitting display device according to the exemplary embodiment of the present disclosure, the auxiliary electrode disposed between two sub pixels is shifted toward both sub pixels by a predetermined distance. Therefore, the auxiliary electrode is in stable contact with the cathode regardless of the misalignment generated during the formation of the partition. By doing this, the Vss is stably supplied and the problem of the luminance ununiformity caused due to the voltage drop in the top emission type organic light emitting display device is solved to improve the luminance uniformity.

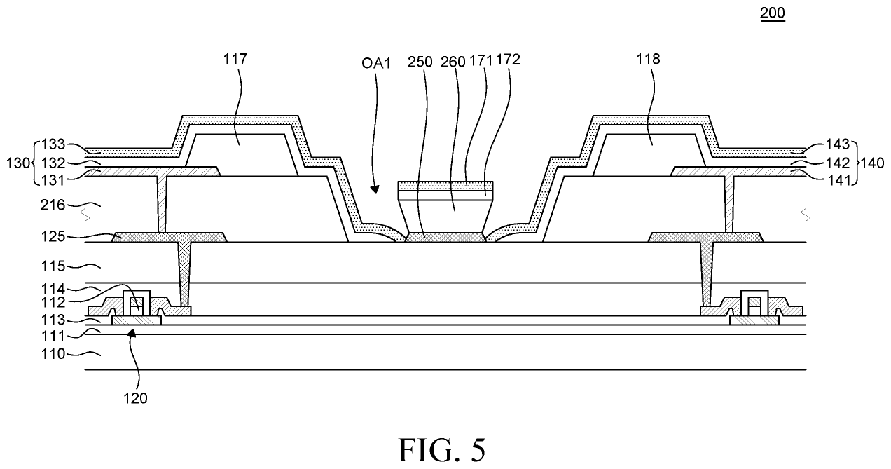

FIGS. 5 to 8 are cross-sectional views illustrating various exemplary embodiments for a formation position of an auxiliary electrode and a partition in an organic light emitting display device according to another exemplary embodiment of the present disclosure.

As compared with the organic light emitting display device 100 illustrated in FIG. 2, only a formation position of the auxiliary electrode 150 and the partition 160 and shapes of the planarization layer, the organic emission layer, and the cathode of organic light emitting display devices illustrated in FIGS. 5 to 8 are different. However, the other components are substantially the same so that a redundant description will be omitted.

It is to be noted that, although the specific structures of the organic light emitting display device 100 are shown in FIGS. 2 to 4, the present disclosure is not limited thereto. For example, the gate structure of the thin film transistor 120 may also be a bottom gate type or a dual gate type, the connection electrode 125 and/or one of the first planarization layer 115 and the second planarization layer 216 may be omitted.

An organic light emitting display device 200 illustrated in FIG. 5 forms a first opening OA1 which exposes a part of a top surface of a first planarization layer 115 between a first sub pixel SP1 and a second sub pixel SP2, on a second planarization layer 216. Therefore, an auxiliary electrode 250 and a partition 260 are formed on the first planarization layer 115 corresponding to the first opening OA. At this time, the auxiliary electrode 250 may be formed of the same material as the connection electrode 125 disposed on the first planarization layer 115. Thereafter, the first organic emission layer 132, the second organic emission layer 142, the first cathode 133, and the second cathode 143 are sequentially deposited so that the first cathode 133 and the second cathode 143 may be in contact with an exposed side surface of the auxiliary electrode 250 disposed in the first opening OA1.

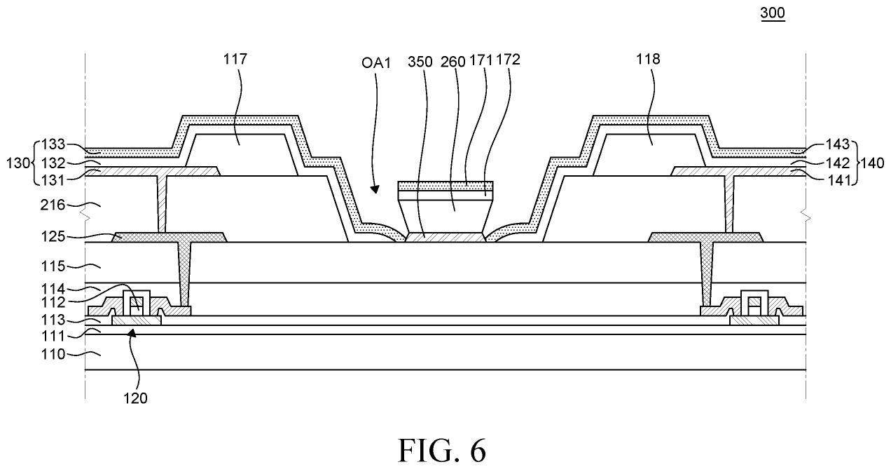

Next, in an organic light emitting display device 300 illustrated in FIG. 6, only a material which configures the auxiliary electrode 350 is different from that of the organic light emitting display device 200 illustrated in FIG. 5, but the other components are substantially the same. In the organic light emitting display device 300 illustrated in FIG. 6, the auxiliary electrode 350 disposed in the first opening OA1 is formed of the same material as the anodes 131 and 141.

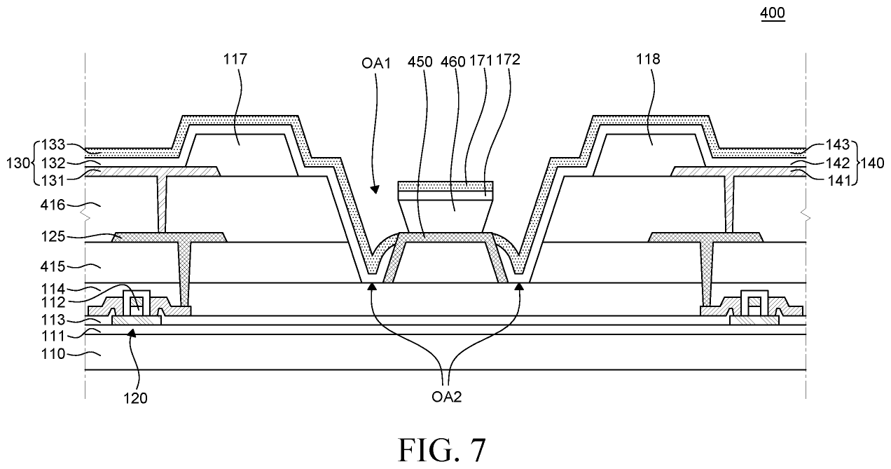

Next, in an organic light emitting display device 400 illustrated in FIG. 7, a second opening OA2 is further formed in a partial area of a first planarization layer 415 overlapping the first opening OA1 as compared with the organic light emitting display device 200 illustrated in FIG. 5. The second opening OA2 exposes a part of the passivation layer 114 which is adjacent to the auxiliary electrode 250 to be located below the first planarization layer 415. At this time, the auxiliary electrode 450 is continuously disposed on a side surface of the first planarization layer 415 exposed by the second opening OA2 and a top surface of the first planarization layer 415 enclosed by the second opening OA2. At this time, the auxiliary electrode 450 is formed of the same material as the connection electrode 125. Next, the first organic emission layer 132, the second organic emission layer 142, the first cathode 133, and the second cathode 143 are sequentially deposited to be in contact with the auxiliary electrode 450 disposed on the side surface of the first planarization layer 415 exposed by the second opening OA2.

As illustrated in FIGS. 5-6, the organic light emitting display device further includes a second planarization layer 116 on the first planarization layer 115. The second planarization layer includes a first opening OA1, exposing a portion of the first planarization layer 115. The auxiliary electrode 150 is disposed on the exposed portion of the first planarization layer 115.

In some embodiments, the first sub pixel SP1 further includes a first connection electrode 125 on the first planarization layer, electrically connected to the first anode electrode (e.g., first anode 131). The first anode electrode (e.g., first anode 131) is on the second planarization layer, and the auxiliary electrode 150 includes a same material as the first anode electrode or the first connection electrode.

In the meantime, in FIG. 7, a structure in which the auxiliary electrode 450 is disposed on both side surfaces of the first planarization layer 415 exposed by the second opening OA2 is illustrated, but the auxiliary electrode 450 may be disposed only on one side surface. As described above with reference to FIG. 2, the auxiliary electrode 450 includes a first auxiliary electrode block, a second auxiliary electrode block, and a third auxiliary electrode block which are shifted to the X-axis direction from each other. Accordingly, the first auxiliary electrode block is disposed on a left side surface and a top surface of the first planarization layer 415 exposed by the second opening OA2 and the third auxiliary electrode block is disposed on a right side surface and the top surface of the first planarization layer 415 exposed by the second opening OA2.

As illustrated in FIG. 7, in some embodiments, the first planarization layer is formed with an opening (e.g., second opening OA2), exposing a side surface of the first planarization layer 115. A portion of the auxiliary electrode extends to cover at least a portion of the side surface of the first planarization layer.

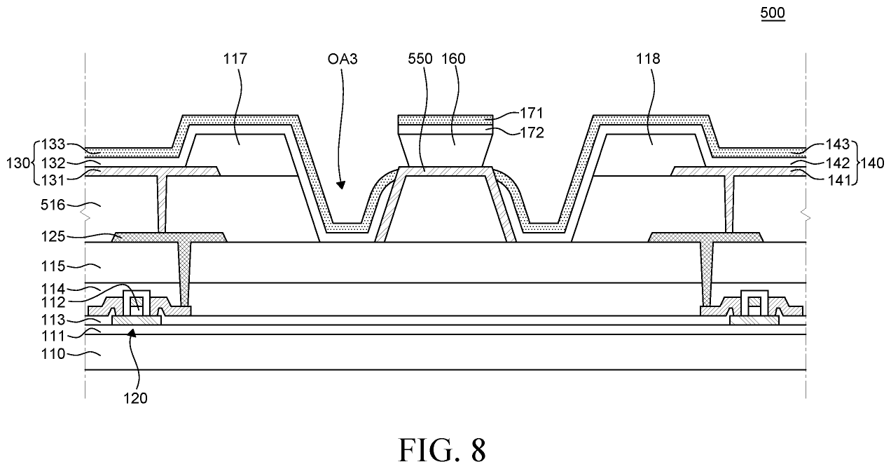

Next, an organic light emitting display device 500 illustrated in FIG. 8 forms a third opening OA3 which exposes a part of a top surface of a first planarization layer 115 between a first sub pixel SP1 and an auxiliary electrode 220 and between a second sub pixel SP2 and the auxiliary electrode 220, on a second planarization layer 516. Unlike the first opening OA1 illustrated in FIG. 5 in which the second planarization layer 216 is removed so as to seat the auxiliary electrode 550 and the partition 160 in an area removed by the opening, a third opening OA3 illustrated in FIG. 8 removes only the second planarization layer 516 in the vicinity of the auxiliary electrode 550 and the partition 160. For example, the third opening OA3 has a shape in which the second planarization layer 516 is removed along a side surface of the partition 160. At this time, the auxiliary electrode 550 and the partition 160 are disposed on the second planarization layer 516 enclosed by the third opening OA3. Specifically, the auxiliary electrode 550 is continuously disposed on a side surface of a second planarization layer 516 exposed by the third opening OA3 and a top surface of the second planarization layer 516 enclosed by the third opening OA3. At this time, the auxiliary electrode 550 is formed of the same material as the anodes 131 and 141. Next, the first organic emission layer 132, the second organic emission layer 142, the first cathode 133, and the second cathode 143 are sequentially deposited to be in contact with the auxiliary electrode 550 disposed on the side surface of the second planarization layer 516 exposed by the third opening OA3.

In the meantime, in FIG. 8, a structure in which the auxiliary electrode 550 is disposed on both side surfaces of the second planarization layer 516 exposed by the third opening OA3 is illustrated, but the auxiliary electrode 550 may be disposed only on one side surface. As described above with reference to FIG. 2, the auxiliary electrode 550 includes a first auxiliary electrode block, a second auxiliary electrode block, and a third auxiliary electrode block which are shifted to the X-axis direction from each other. Accordingly, the first auxiliary electrode block is disposed on a left side surface and a top surface of the second planarization layer 516 exposed by the third opening OA3 and the third auxiliary electrode block is disposed on a right side surface and the top surface of the second planarization layer 516 exposed by the third opening OA3.

As illustrated in FIG. 8, the organic light emitting display device further includes a second planarization layer 516 on the first planarization layer 115. The second planarization layer 516 is formed with an opening, exposing a portion of the first planarization layer. The auxiliary electrode 150 is disposed on a top surface of the second planarization layer 516, and a portion of the auxiliary electrode 150 extends to cover at least a portion of the side surface of the second planarization layer 516.

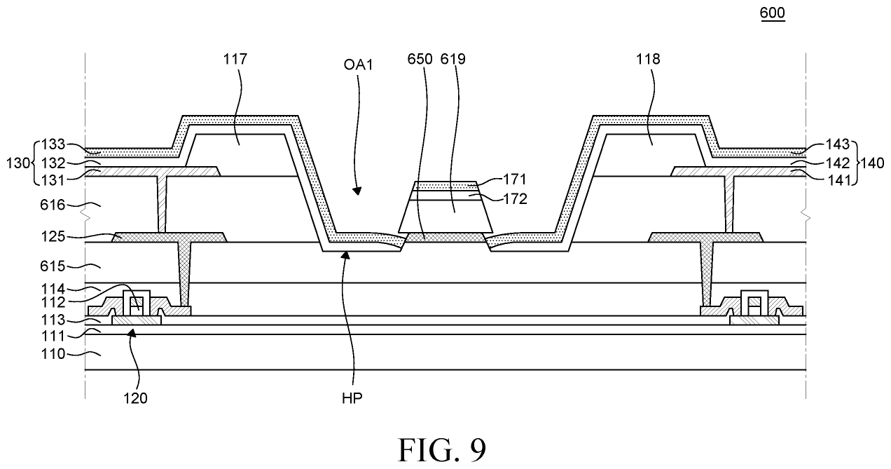

FIG. 9 is a cross-sectional view illustrating a structure of an auxiliary electrode and a partition in an organic light emitting display device according to still another exemplary embodiment of the present disclosure. As compared with the organic light emitting display device 200 illustrated in FIG. 5, in an organic light emitting display device illustrated in FIG. 9, shapes of a first planarization layer 615 and an auxiliary electrode 650 are different and a third bank layer 619, instead of the partition, is disposed on the auxiliary electrode 650. However, the other components are substantially the same so that a redundant description will be omitted.

Referring to FIG. 9, a second planarization layer 616 includes a first opening OA1 which exposes a part of a top surface of the first planarization layer 615 so as to seat the auxiliary electrode 650. At this time, the first planarization layer 615 includes a groove portion HP which is formed in the vicinity of the auxiliary electrode 650 disposed above the first planarization layer 615 and is downwardly recessed. The groove portion HP forms a surface to be lower than a top surface of the first planarization layer 616 on which the auxiliary electrode 650 is formed. A thickness of the groove portion HP may be smaller than the thicknesses of the organic emission layers 132 and 142.

The organic light emitting display device 600 illustrated in FIG. 9 does not form a separate partition 160. Specifically, a third bank layer 619 is also formed on the auxiliary electrode 650 during a process of forming a first bank layer 117 and a second bank layer 118 after forming a first opening OA1 in the second planarization layer 616. Next, during an etching process for forming the groove portion HP in the first planarization layer 615, the auxiliary electrode 650 is etched to be located inside more than the third bank layer 619. Due to this structure, a separate partition having a reverse taper shape is not formed, but the organic emission layers 132 and 142 are disconnected from the auxiliary electrode 650 by a step formed thereabove and the cathodes 133 and 143 are in contact with a side surface of the auxiliary electrode 650.

As illustrated in FIG. 9, in some embodiments, the first planarization layer 115 is formed with a first groove portion HP and a second groove portion. The auxiliary electrode 150 is disposed on a top surface of the first planarization layer 115 between the first groove portion HP and the second groove portion. A portion of the first organic light emission layer 132 and a portion of the first cathode electrode (e.g., first cathode 133) extend into the groove portion.

The exemplary embodiments of the present disclosure can also be described as follows:

According to an embodiment of the present disclosure, there is provided an organic light emitting display device. The organic light emitting display device comprises a substrate including a first sub pixel and a second sub pixel disposed in a first direction; a thin film transistor disposed on the substrate and corresponds to each of the first sub pixel and the second sub pixel; a planarization layer on the thin film transistor; an organic light emitting diode which is disposed on the planarization layer so as to correspond to each of the first sub pixel and the second sub pixel and has an anode, an organic emission layer, and a cathode; an auxiliary electrode between the first sub pixel and the second sub pixel; and a partition which is disposed on the auxiliary electrode so as to at least partially overlap the auxiliary electrode. The auxiliary electrode protrudes toward the first sub pixel and the second sub pixel from corners of the partition in plan view.

The auxiliary electrode may extend in a second direction perpendicular to the first direction and include a first protrusion protruding toward the first sub pixel and a second protrusion protruding toward the second sub pixel in the first direction.

The auxiliary electrode may extend to a second direction perpendicular to the first direction and form a plurality step structures in plan view while maintaining a predetermined thickness.

The auxiliary electrode may include a first auxiliary electrode block, a second auxiliary electrode block, and a third auxiliary electrode block which are sequentially disposed in a second direction perpendicular to the first direction, the first auxiliary electrode block may be shifted toward the first sub pixel by a predetermined distance from the second auxiliary electrode block, and the third auxiliary electrode block may be shifted toward the second sub pixel by a predetermined distance from the second auxiliary electrode block.

A part of the first auxiliary electrode block and the third auxiliary electrode block may not overlap the partition.

The partition may have a shape extending in the second direction, and the partition may cover a corner of the first auxiliary electrode block adjacent to the second sub pixel and may cover a corner of the third auxiliary electrode block adjacent to the first sub pixel.

The partition may have a reverse taper shape.

The organic emission layer may be formed to be in contact with a side surface of the auxiliary electrode and the cathode is formed on the organic emission layer to be in contact with a side surface of the auxiliary electrode.

The auxiliary electrode may be disposed on the planarization layer and is formed of the same material as the anode.

The planarization layer may include a first planarization layer which planarizes the thin film transistor; and a second planarization layer which is disposed on the first planarization layer and includes a first opening which exposes at least a part of the first planarization layer between the first sub pixel and the second sub pixel, the anode may be disposed on the second planarization layer, and the auxiliary electrode may be disposed on the first planarization layer in the first opening.

The organic light emitting display device according may further comprise a connection electrode which is disposed on the first planarization layer and connects a drain electrode and the anode of the thin film transistor. The auxiliary electrode may be formed of the same material as the connection electrode or the anode.

The first planarization layer may include a second opening adjacent to the auxiliary electrode, the auxiliary electrode may cover a side surface of the first planarization layer exposed by the second opening, and the organic emission layer and the cathode may be formed to be in contact with an auxiliary electrode disposed on a side surface of the first planarization layer.

The planarization layer may include a first planarization layer which planarizes the thin film transistor and a second planarization layer which is disposed on the first planarization layer, the second planarization layer may include a third opening which is adjacent to the first sub pixel to expose a part of the first planarization layer and a fourth opening which is adjacent to the second sub pixel to expose a part of the first planarization layer, and the auxiliary electrode may be disposed on the second planarization layer located between the third opening and the fourth opening.

The auxiliary electrode may be formed of the same material as the anode and cover a side surface of the second planarization layer exposed by the third opening and the fourth opening, and the organic emission layer and the cathode may be formed to be in contact with an auxiliary electrode disposed on a side surface of the second planarization layer.

The first planarization layer may further include a groove portion which is formed in the vicinity of the auxiliary electrode so as to correspond to the first opening, the auxiliary electrode may be located inside more than a corner of the partition, the organic emission layer and the cathode are located in the groove portion and the cathode may be in contact with a side surface of the auxiliary electrode.

The partition may be formed of the same material as the bank layer and has a taper shape.

According to another embodiment of the present disclosure, an organic light emitting display device includes a first sub pixel, a second sub pixel, an auxiliary electrode between the first sub pixel and the second sub pixel, and a partition on the auxiliary electrode. The first sub pixel includes a first anode electrode, a first organic light emitting layer, and a first cathode electrode. The second sub pixel includes a second anode electrode, a second organic light emitting layer, and a second cathode electrode. The auxiliary electrode is disposed on at least a first planarization layer. The auxiliary electrode includes at least a first portion and a second portion. The first portion protrudes further than an edge of the second portion in a first direction. The partition at least partially overlaps the auxiliary electrode. At least one of the first cathode or the second cathode contacts the first portion of the auxiliary electrode.

In some embodiments, the auxiliary electrode further includes a third portion that protrudes further than another edge of the second portion of the auxiliary electrode in a second direction opposite to the first direction.

In some embodiments, the first cathode electrode contacts the first portion of the auxiliary electrode, and the second cathode electrode contacts the third portion of the auxiliary electrode.

In some embodiments, the first direction is toward the first sub pixel, and the second direction is toward the second sub pixel.

In some embodiments, the partition covers an edge of the first portion of the auxiliary electrode.

In some embodiments, the first cathode electrode is electrically connected to the auxiliary electrode, and the first anode electrode, the second anode electrode, and the auxiliary electrode include a same material.

In some embodiments, the organic light emitting display device further includes a second planarization layer on the first planarization layer. The second planarization layer includes a first opening, exposing a portion of the first planarization layer, and the auxiliary electrode is disposed on the exposed portion of the first planarization layer.

In some embodiments, the first sub pixel further includes a first connection electrode on the first planarization layer, electrically connected to the first anode electrode. The first anode electrode is on the second planarization layer, and the auxiliary electrode includes a same material as the first anode electrode or the first connection electrode.

In some embodiments, the first planarization layer is formed with an opening, exposing a side surface of the first planarization layer. A portion of the auxiliary electrode extends to cover at least a portion of the side surface of the first planarization layer.

In some embodiments, the first planarization layer is formed with a first groove portion and a second groove portion. The auxiliary electrode is disposed on a top surface of the first planarization layer between the first groove portion and the second groove portion. A portion of the first organic light emitting layer and a portion of the first cathode electrode extend into the first groove portion.

In some embodiments, the organic light emitting display device further includes a second planarization layer on the first planarization layer. The second planarization layer is formed with an opening, exposing a portion of the first planarization layer. The auxiliary electrode is disposed on a top surface of the second planarization layer, and a portion of the auxiliary electrode extends to cover at least a portion of a side surface of the second planarization layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting display device, comprising:
a substrate including a first sub pixel and a second sub pixel disposed in a first direction;
a thin film transistor disposed on the substrate and corresponds to each of the first sub pixel and the second sub pixel;
a planarization layer on the thin film transistor;
an organic light emitting diode which is disposed on the planarization layer so as to correspond to each of the first sub pixel and the second sub pixel and has an anode, an organic emission layer, and a cathode;
an auxiliary electrode between the first sub pixel and the second sub pixel; and
a partition which is disposed on the auxiliary electrode so as to at least partially overlap the auxiliary electrode,
wherein the auxiliary electrode protrudes toward the first sub pixel and the second sub pixel from corners of the partition in plan view.

2. The organic light emitting display device according to claim 1, wherein the auxiliary electrode extends in a second direction perpendicular to the first direction and includes a first protrusion protruding toward the first sub pixel and a second protrusion protruding toward the second sub pixel in the first direction.

3. The organic light emitting display device according to claim 1, wherein the auxiliary electrode extends to a second direction perpendicular to the first direction and forms a plurality step structures in plan view while maintaining a predetermined thickness.

4. The organic light emitting display device according to claim 1, wherein the auxiliary electrode includes a first auxiliary electrode block, a second auxiliary electrode block, and a third auxiliary electrode block which are sequentially disposed in a second direction perpendicular to the first direction, the first auxiliary electrode block is shifted toward the first sub pixel by a predetermined distance from the second auxiliary electrode block, and the third auxiliary electrode block is shifted toward the second sub pixel by a predetermined distance from the second auxiliary electrode block.

5. The organic light emitting display device according to claim 4, wherein a part of the first auxiliary electrode block and the third auxiliary electrode block does not overlap the partition.

6. The organic light emitting display device according to claim 5, wherein the partition has a shape extending in the second direction, and the partition covers a corner of the first auxiliary electrode block adjacent to the second sub pixel and covers a corner of the third auxiliary electrode block adjacent to the first sub pixel.

7. The organic light emitting display device according to claim 4, wherein the organic emission layer is formed to be in contact with a side surface of the auxiliary electrode and the cathode is formed on the organic emission layer to be in contact with a side surface of the auxiliary electrode.

8. The organic light emitting display device according to claim 1, wherein the auxiliary electrode is disposed on the planarization layer and is formed of a same material as the anode.

9. The organic light emitting display device according to claim 1, wherein the planarization layer includes a first planarization layer which planarizes the thin film transistor; and a second planarization layer which is disposed on the first planarization layer and includes a first opening which exposes at least a part of the first planarization layer between the first sub pixel and the second sub pixel, the anode is disposed on the second planarization layer, and the auxiliary electrode is disposed on the first planarization layer in the first opening.

10. The organic light emitting display device according to claim 9, further comprising:
a connection electrode which is disposed on the first planarization layer and connects a drain electrode and the anode of the thin film transistor,
wherein the auxiliary electrode is formed of a same material as the connection electrode or the anode.

11. The organic light emitting display device according to claim 9, wherein the first planarization layer includes a second opening adjacent to the auxiliary electrode, the auxiliary electrode covers a side surface of the first planarization layer exposed by the second opening, and the organic emission layer and the cathode are formed to be in contact with an auxiliary electrode disposed on a side surface of the first planarization layer.

12. The organic light emitting display device according to claim 1, wherein the planarization layer includes a first planarization layer which planarizes the thin film transistor and a second planarization layer which is disposed on the first planarization layer, the second planarization layer includes a third opening which is adjacent to the first sub pixel to expose a part of the first planarization layer and a fourth opening which is adjacent to the second sub pixel to expose a part of the first planarization layer, and the auxiliary electrode is disposed on the second planarization layer located between the third opening and the fourth opening.

13. The organic light emitting display device according to claim 12, wherein the auxiliary electrode is formed of a same material as the anode and covers a side surface of the second planarization layer exposed by the third opening and the fourth opening, and the organic emission layer and the cathode are formed to be in contact with an auxiliary electrode disposed on a side surface of the second planarization layer.

14. The organic light emitting display device according to claim 9, wherein the first planarization layer further includes a groove portion which is formed surrounding the auxiliary electrode so as to correspond to the first opening, the auxiliary electrode is located inside more than a corner of the partition, the organic emission layer and the cathode are located in the groove portion and the cathode is in contact with a side surface of the auxiliary electrode.

15. The organic light emitting display device according to claim 14, wherein the partition is formed of a same material as a bank layer disposed on the planarization layer to define an emission area of each of the first sub pixel and the second sub pixel and has a taper shape.

16. The organic light emitting display device according to claim 1, further comprising:
a dummy organic layer formed of a same material as the organic emission layer and disposed on the partition, and
a dummy conductive layer formed of the same material as the cathode and disposed on the dummy organic layer

17. An organic light emitting display device, comprising:
a first sub pixel, the first sub pixel including:
a first anode electrode,
a first organic light emitting layer, and
a first cathode electrode;
a second sub pixel, the second sub pixel including:
a second anode electrode,
a second organic light emitting layer, and
a second cathode electrode;
an auxiliary electrode between the first sub pixel and the second sub pixel, the auxiliary electrode disposed on at least a first planarization layer and comprising at least a first portion and a second portion, wherein the first portion protrudes further than an edge of the second portion in a first direction; and
a partition on the auxiliary electrode, the partition at least partially overlapping the auxiliary electrode,
wherein at least one of the first cathode electrode or the second cathode electrode contacts the first portion of the auxiliary electrode.

18. The organic light emitting display device of claim 17, wherein the auxiliary electrode further comprises a third portion that protrudes further than another edge of the second portion of the auxiliary electrode in a second direction opposite to the first direction,
the first direction is toward the first sub pixel, and the second direction is toward the second sub pixel.

19. The organic light emitting display device of claim 17, wherein the auxiliary electrode further comprises a third portion protruding farther than another edge of the second portion, wherein the first cathode electrode contacts the first portion of the auxiliary electrode and the second cathode electrode contacts the third portion of the auxiliary electrode.

20. The organic light emitting display device of claim 17, wherein the partition covers an edge of the first portion of the auxiliary electrode.
